(19) United States
(12) Patent Application Publication
(10) Pub. No.: US 2016/0100485 A1
(43) Pub. Date: Apr. 7, 2016

(54) PRINTED CIRCUIT BOARD AND MANUFACTURING METHOD THEREOF

(71) Applicant: SAMSUNG ELECTRO-MECHANICS CO., LTD., Suwon-Si (KR)

(72) Inventors: Hye-Won JUNG, Suwon-Si (KR); Myung-Sam KANG, Suwon-Si (KR); Yong-Wan JI, Suwon-Si (KR); Yong-Jin PARK, Suwon-Si (KR); Young-Gwan KO, Suwon-Si (KR); Kang-Wook BONG, Suwon-Si (KR)

(21) Appl. No.: 14/636,076

(22) Filed: Mar. 2, 2015

(30) Foreign Application Priority Data
Oct. 2, 2014 (KR) 10-2014-0133217

(51) Int. Cl. H05K 1/11; H05K 3/42; H05K 3/00; H05K 3/10

(52) U.S. Cl. CPC H05K 1/115; H05K 3/10; H05K 3/429; H05K 3/0094

(57) ABSTRACT

Disclosed are a printed circuit board and a method of manufacturing the printed circuit board, which includes: a first resist layer; a first circuit formed on the first resist layer; an insulation film formed on the first resist layer so as to cover an upper surface and a lateral surface of the first circuit; a ground formed on the insulation film so as to be connected with the first circuit electrically; and an insulation layer formed on the insulation film so as to cover the ground.

### CROSS-REFERENCE TO RELATED APPLICATIONS

This application claims the benefit of Korean Patent Application No. 10-2014-0133217, filed with the Korean Intellectual Property Office on Oct. 2, 2014, the disclosure of which is incorporated herein by reference in its entirety.

### BACKGROUND

1. Technical Field

The present invention relates to a printed circuit board and a method of manufacturing a printed circuit board.

2. Background Art

Printed circuit boards have become essential components in nearly every electronics-related industrial field, including home electronic appliances, such as TVs, cameras and VCRs, and telecommunications devices, such as computers and portable terminals. As electronic devices have become increasingly converged, their components need to be smaller, making the board more important than ever.

The printed circuit boards are mainly classified into flexible PCBs and rigid PCBs according to their rigidity, and classified into one-side PCBs, double-side PCBs and multi-layered PCBs according to the number of circuit pattern layers. The printed circuit boards used for electronic devices have been increasingly thinner and multi-layered in order to implement various, complex functions within the thin board. Moreover, to cope with this trend, the patterns of the printed circuit boards have been increasingly finer.

The related art of the present invention is disclosed in Korea Patent Publication No. 10-2013-0068656 (Jun. 26, 2013).

### SUMMARY

The present invention provides a printed circuit board and a method of manufacturing a printed circuit board.

An aspect of the present invention provides a printed circuit board with a reduced thickness by insulating a circuit with an insulation film. The printed circuit board may include a first resist layer, a first circuit, an insulation film, a ground and an insulation layer.

The printed circuit board may further include a connecting portion penetrating the insulation film so as to be interposed between the first circuit and the ground, and the connecting portion may be formed by filling a hole formed in the insulation film with a conductive material that is the same as a conductive material of the ground. One side of the connecting portion may be in contact with the first circuit, and the other side of the connecting portion may be in contact with the ground. The insulation film may be thinner than or as thin as the first circuit, and the insulation film may be formed by use of deposition.

The printed circuit board may further include a second circuit, a via and a second resist layer, and the second circuit may be positioned above the ground.

Another aspect of the present invention provides a method of manufacturing a printed circuit board with a reduced thickness by insulating a circuit and a ground with an insulation film.

The method of manufacturing a printed circuit board may include: providing a core material; forming a first circuit on the core material; forming an insulation film for covering an upper surface and a lateral surface of the first circuit; forming a ground on the insulation film; and forming an insulation layer for covering the ground.

The method of manufacturing a printed circuit board may further include: forming a connecting portion; forming a via; and forming a second circuit. The forming of the connecting portion may include: forming a hole in the insulation film; and filling the hole with a conductive material.

### BRIEF DESCRIPTION OF DRAWINGS

FIG. 1 shows a printed circuit board in accordance with an embodiment of the present invention.

FIG. 2 is a flow diagram showing a method of manufacturing a printed circuit board in accordance with an embodiment of the present invention.

FIG. 3, FIG. 4, FIG. 5, FIG. 6, FIG. 7, FIG. 8, FIG. 9, FIG. 10, FIG. 11 and FIG. 12 show processes of the method of manufacturing a printed circuit board in accordance with an embodiment of the present invention.

### DETAILED DESCRIPTION

Hereinafter, a printed circuit board and a method of manufacturing a printed circuit board in accordance with the present invention will be described with reference to the accompanying drawings. In describing the present invention with reference to the accompanying drawings, any identical or corresponding elements will be assigned with same reference numerals, and their description will not be provided redundantly.

Terms such as “first” and “second” may be used in describing various elements, but the above elements shall not be restricted to the above terms. The above terms are used only to distinguish one element from the other.

When one element is described to be “coupled” to another element, it does not refer to a physical, direct contact between these elements only, but it shall also include the possibility of yet another element being interposed between these elements and each of these elements being in contact with said yet another element.

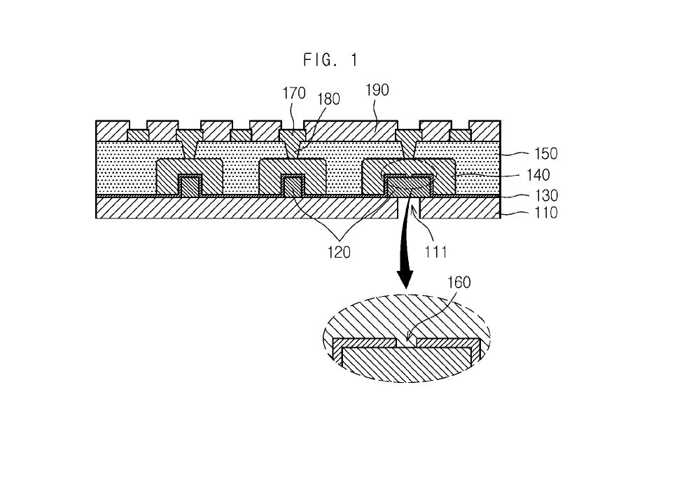

FIG. 1 shows a printed circuit board in accordance with an embodiment of the present invention.

Referring to FIG. 1, the printed circuit board in accordance with an embodiment of the present invention may include a first resist layer 110, a first circuit 120, a first insulation film 130, a ground 140 and an insulation layer 150, and may further include a connecting portion 160, a second circuit 170, a via 180 and a second resist layer 190.

The first resist layer 110, which is placed at a bottom layer of the printed circuit board, may be a solder resist. The first resist layer 110 protects the first circuit 120 and keeps the first circuit 120 from being short-circuited unnecessarily.

The first resist layer 110 may have an opening 111 formed therein. The first circuit 120 may function as a pad by having a portion thereof exposed through the opening 111 of the first resist layer 110. The portion of the first circuit 120 functioning as the pad may be surface-treated so as to prevent any corrosion and/or damage by foreign substances.

The first circuit 120 is a circuit pattern formed on the first resist layer 110. The first circuit 120 may be made of a metal such as copper and may have a thickness of about 10 um.

The insulation film 130, which is a film that insulates the first circuit 120, is formed on the first resist layer 110 so as to cover an upper surface and lateral surfaces of the first circuit 120. The insulation film 130 may cover not only the upper and lateral surfaces of the first circuit 120 but also a surface of the first resist layer 110. In such a case, the insulation film 130 may have a curvature along a surface of the first circuit 120.

The insulation film 130 may have a thickness that is uniform and smaller than that of the first circuit 120. If the thickness of the first circuit 120 is about 10 um, the thickness of the insulation film 130 may be between 5 um and 10 um, inclusive.

The insulation film 130 may be formed by use of deposition, for example, chemical vapor deposition (CVD). In such a case, the insulation film 130 may be made of Parylene.

The ground 140, which is a wired layer configured for grounding, shield and heat dissipation, functions to preserve a signal transferred to the first circuit 120. The function of the ground 140 becomes particularly important if the signal is high frequency waves, which tend to radiate.

The ground 140 is formed on the insulation film 130 and is electrically connected with the first circuit 120. At least a portion of the ground 140 may be positioned above the first circuit 120. Moreover, as illustrated in FIG. 1, at least a portion of the ground 140 may be positioned at a lateral side of the first circuit 120.

The ground 140 may be formed on a surface of the insulation film 130. In such a case, one surface of the insulation film 130 may be in contact with the first circuit 120, and the other surface of the insulation film 130 may be in contact with the ground 140. By having the insulation film 130 formed uniformly in between the ground 140 and the first circuit 120, a distance between the ground and the first circuit may become uniform.

The connecting portion 160 is interposed between the first circuit 120 and the ground 140 so as to connect the first ground 120 with the ground 140 electrically. One side of the connecting portion 160 may be in contact with the first circuit 120, and the other side of the connecting portion 160 may be in contact with the ground 140. In such a case, the one side of the connecting portion 160 may be in contact with the upper surface of the first circuit 120. In such a case, a thickness of the connecting portion 160 may be the same as that of the insulation film 130.

The connecting portion 160 is formed by penetrating the insulation film 130. The connecting portion 160 may be formed by filling a hole 161 that is formed in the insulation film 130 with a conductive material, which may be the same as that used to form the ground 140. That is, the connecting portion 160 and the ground 140 may be made of a same conductive material, in which case the connecting portion 160 and the ground 140 may be formed simultaneously. Here, the conductive material may be a metal such as copper.

The insulation layer 150, which is a layer that insulates the ground 140, may be formed on the insulation film 130. The insulation layer 150 may be thicker than the insulation film 130. The insulation layer 150 may cover the ground 140 by being formed to be thicker than the ground 140. The insulation layer 150 may be made of ABF (Ajinomoto Build-up Film) or prepreg (PPG).

The second circuit 170 is a circuit pattern formed on the insulation layer 150 so as to be connected with the ground 140 electrically. Like the first circuit 120, the second circuit may be made of a metal such as copper and may have a thickness of about 10 um.

The via 180 is a connector that connects the ground 140 with the second circuit 170 electrically by being interposed between the ground 140 and the second circuit 170. The via 180 is formed within the insulation layer 150.

The second resist layer 190 is a layer that covers the second circuit 170 in order to protect the second circuit 170. The second resist layer 170 may be made of a solder resist.

The second resist layer 190 may expose a portion of the second circuit 170. The portion of the second circuit 170 that is not covered by the second resist layer but is exposed may function as a pad and may be surface-treated so as to prevent any corrosion and/or damage by foreign substances.

Hitherto, the printed circuit board in accordance with an embodiment of the present invention has been described. Hereinafter, a method of manufacturing the printed circuit board in accordance with an embodiment of the present invention will be described.

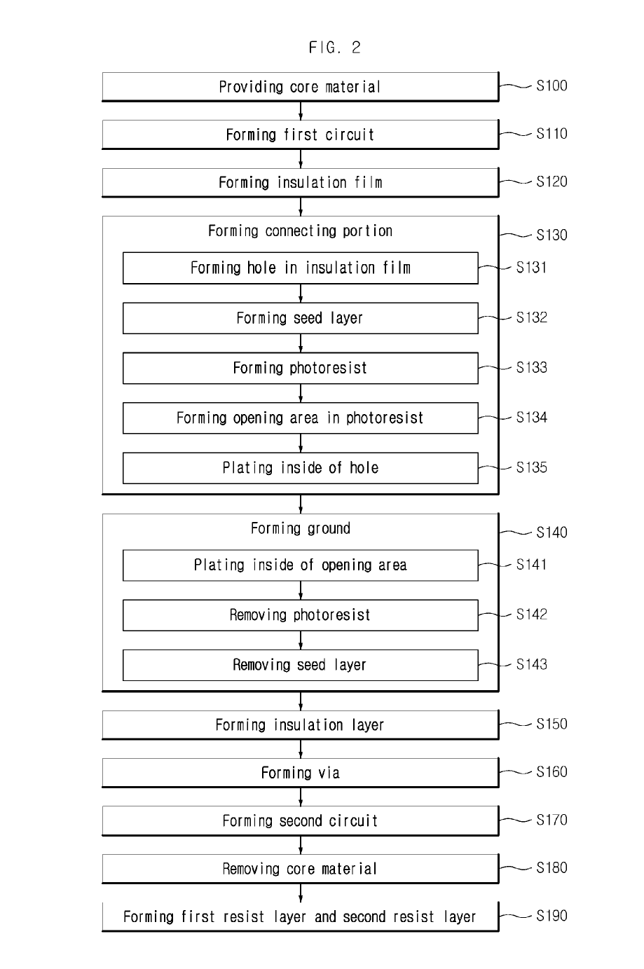

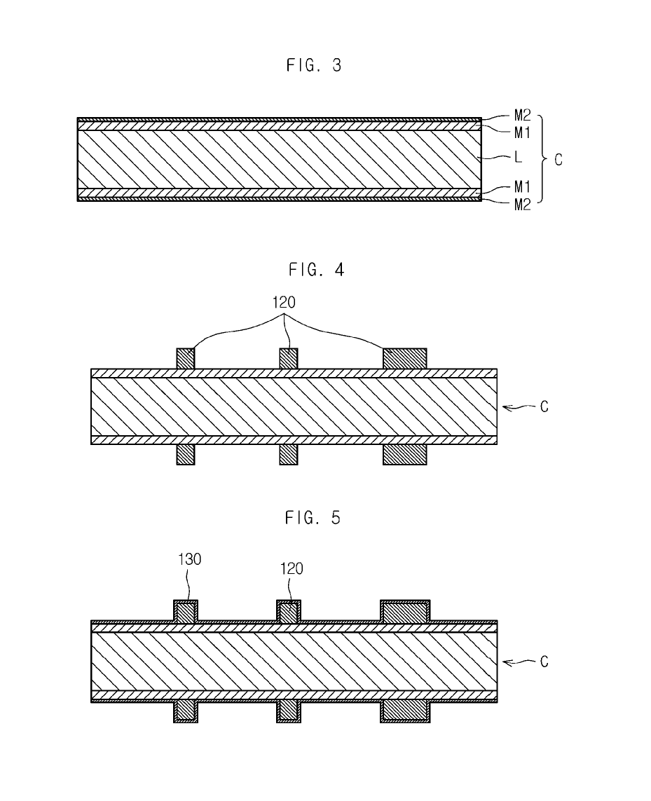

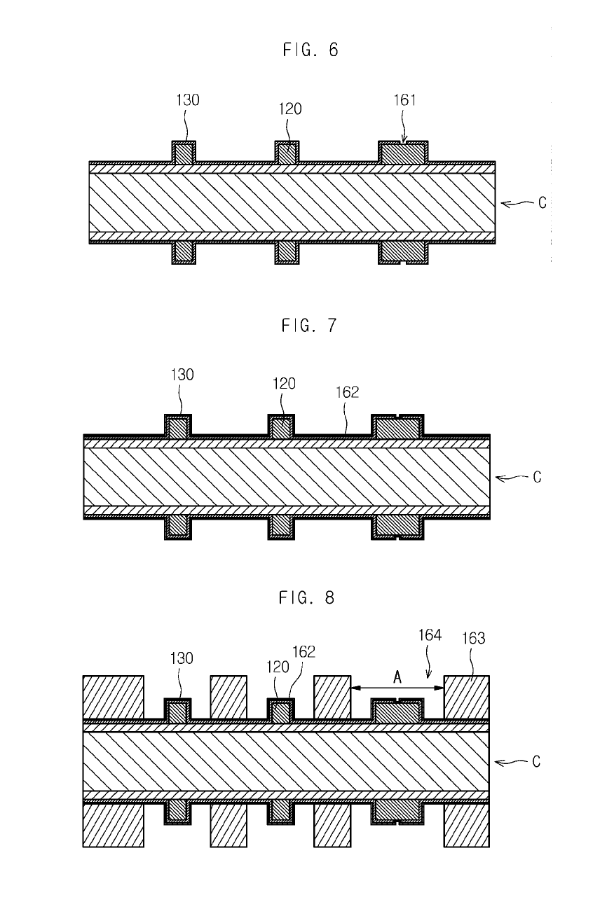

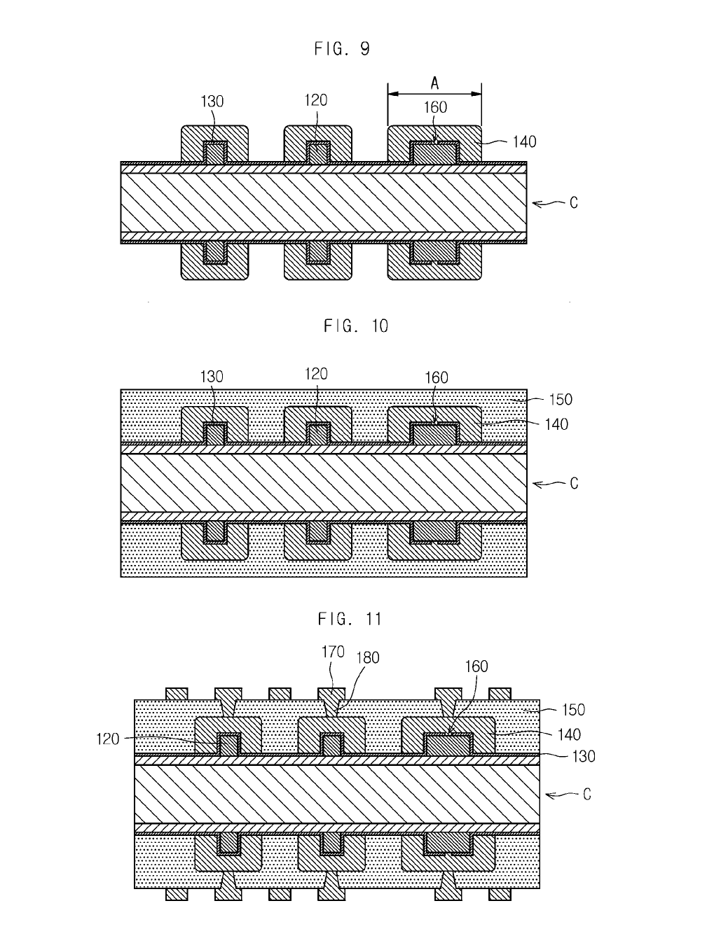

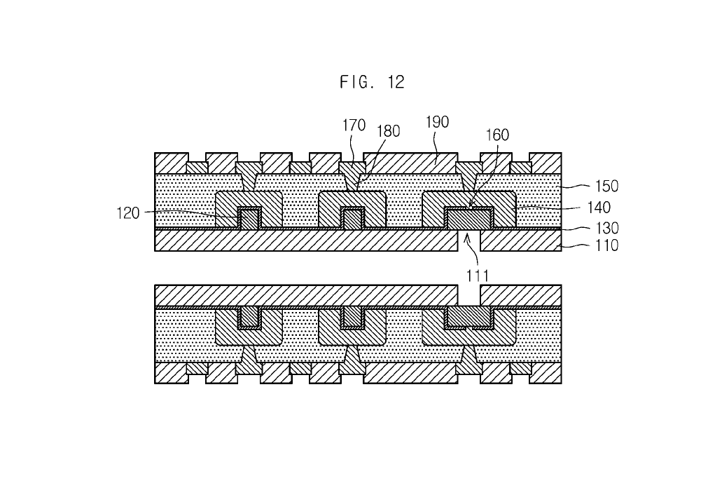

FIG. 2 is a flow diagram showing a method of manufacturing the printed circuit board in accordance with an embodiment of the present invention. FIG. 3, FIG. 4, FIG. 5, FIG. 6, FIG. 7, FIG. 8, FIG. 9, FIG. 10, FIG. 11 and FIG. 12 show processes of the method of manufacturing the printed circuit board in accordance with an embodiment of the present invention.

Referring to FIG. 2, the method of manufacturing the printed circuit board in accordance with an embodiment of the present invention may include: providing a core material (S100); forming a first circuit (S110); forming an insulation film (S120); forming a connecting portion (S130); forming a ground (S140); forming an insulation layer (S150); forming a via (S160); forming a second circuit (S170); removing the core material (S180); and forming a first resist layer and a second resist layer (S190).

Referring to FIG. 3, in the providing of a core material C (S100), the core material C is prepared for temporary use in order to fabricate a printed circuit board.

The core material C may include an insulation material L and a first metal layer M1 and may further include a second metal layer M2. The first metal layer M1 may be formed on one surface or both surfaces of the insulation material L, and the second metal layer M2 may be formed on the first metal layer M1. The first metal layer M1 and the second metal layer M2 may be both made of a metal such as copper.

The second metal layer M2 may function as a seed in the forming of a first circuit 120 (S110). In such a case, the first metal layer M1 may be thicker than the second metal layer M2. For instance, the thickness of the first metal layer M1 may be 18 um, and the second metal layer M2 between 2 um and 5 um.

Referring to FIG. 4, in the forming of the first circuit 120 (S110), the first circuit 120 is formed on the core material C for a signal flow. The first circuit 120 may be made of a metal, with a thickness of about 10 um. The first circuit 120 may be formed by a modified semi additive process (MSAP) or a tenting process.

In the case where the first circuit 120 is plated by way of the above process, the second metal layer M2 of the core material C functions as the seed, and the second metal layer M2 may be removed by, for example, etching, after the plating is completed.

Referring to FIG. 5, in the forming of an insulation film 130 (S120), the insulation film 130 that insulates the first circuit 120 is formed on the core material C. The insulation film 130 may be formed on a surface of the core material C so as to cover an upper surface and lateral surface of the first circuit 120 and may have a curvature along a surface of the first circuit 120.

The insulation film 130 may have a uniform thickness, which may be smaller than or equal to that of the first circuit 120. For example, in case the thickness of the first circuit 120 is about 10 um, the thickness of the insulation film 130 may be greater than or equal to 5 um and smaller than or equal to 10 um.

The insulation film 130 may be formed by use of deposition, for example, chemical vapor deposition (CVD). In such a case, the insulation film 130 may be made of Parylene.

Referring to FIG. 6, FIG. 7, FIG. 8 and FIG. 9, in the forming of a connecting portion 160 (S130), the connecting portion 160 that electrically connects the first circuit 120 with a ground 140, which will be described later, is formed on the insulation film 130. The connecting portion 160 and the ground 140 may be made of a same conductive material, for example, a metal such as copper.

The forming of the connecting portion 160 (S130) may include forming a hole 161 in the insulation film 130 and filling the hole 161 with the conductive material. Here, the filling of the hole 161 with the conductive material may include plating an inside of the hole 161 with the conductive material.

Specifically, the forming of the connecting portion 160 (S130) may include: forming the hole 161 in the insulation film 130 (S131); forming a seed layer 162 (S132); forming a photoresist 163 (S133); forming an opening area 164 in the photoresist 163 (S134); and plating the inside of the hole 161 (S135).

In the forming of the hole 161 in the insulation film 130 (S131), the insulation film 130 is penetrated so as to allow a portion of the first circuit 120 is exposed. The hole 161 may be formed in the shape of a reversed trapezoid.

The hole 161 may be formed by plasma etching. Specifically, the hole 161 may be formed by coating a photosensitive resist on the insulation film 130, patterning the photosensitive resist by exposing and developing, and then plasma etching the photosensitive resist. Moreover, the hole 161 may be formed by use of laser, in which case a CO₂ laser may be used.

In the forming of the seed layer 162 (S132), a thin metallic film is formed by chemical copper plating or sputtering. The seed layer 162 may be thinner than the insulation film 130, in which case the seed layer 162 may not fill the hole 161 completely.

The forming of the seed layer 162 (S132) may be introduced in case plating is used for filling the hole 161 and forming the ground 140 and may be omitted if not necessary.

In the forming of the photoresist 163 (S133), the photoresist 163 that may be patterned by exposing and developing processes is formed on the seed layer 162.

In the forming of the opening area 164 in the photoresist 163 (S134), the opening area 164 is formed by removing a portion of the photoresist 163 in such a way that the seed layer 162 corresponding to the hole 161 is exposed.

As shown in FIG. 8 and FIG. 9, a position of the opening area 164 may correspond to a position of the ground 140. In such a case, a width A of the opening area 164 may be identical with a width A of the ground 140. Here, the term “identical” does not necessarily mean geometric identicalness but means substantial identicalness considering a tolerance within a permissible range.

In the plating of the inside of the hole 161 (S135), the inside of the hole 161 is plated with a conductive material so as to fill the hole 161.

In the forming of the ground 140 (S140), the ground 140 that is electrically connected with the first circuit 120 is formed on the insulation film 130.

The ground 140, which is a wired layer having grounding, shielding and heat-dissipating functions, may be electrically connected with the first circuit 120 through the connecting portion 160.

The ground 140 may be formed on a surface of the insulation film 130. At least a portion of the ground 140 may be positioned above the first circuit 120. Moreover, at least a portion of the ground 140 may be positioned at a lateral side of the first circuit 120.

The ground 140 may be formed by plating by use of the seed layer 162 and the photoresist 163. Specifically, the forming of the ground 140 (S140) may include: plating an inside of the opening area 164 (S141); removing the photoresist 163 (S142); and removing the seed layer 162 (S143).

In the plating of the inside of the opening area 164 (S141), the inside of the opening area 164 is plated using the seed layer 162 if the position of the opening area 164 of the photoresist 163 corresponds to the position of the ground 140.

In such a case, the connecting portion 160 and the ground 140 may be simultaneously plated using the same seed layer 162 and photoresist 163. That is, the opening area 164 of the photoresist 163 may be simultaneously plated when the hole 161 is plated. Here, the seed layer 162, the connecting portion 160 and the ground 140 may be made of a same conductive material.

In the removing of the photoresist 163 (S142), any remaining photoresist 163 is removed. The photoresist 163 may be exfoliated.

In the removing of the seed layer 162 (S143), any unnecessary seed layer 162 is removed. That is, the seed layer 162 that is exposed due to the removal of the photoresist 163 is removed. The seed layer 162 may be etched off.

Referring to FIG. 10, in the forming of an insulation layer 150 (S150), the insulation layer 150 configured for insulation of the ground 140 is formed on the insulation film 130. The insulation layer 150 may be thicker than the insulation film 130. The insulation layer 150 may cover the ground 140 by being formed to be thicker than the ground 140. The insulation layer 150 may be made of ABF (Ajinomoto Build-up Film) or prepreg (PPG).

Referring to FIG. 11, in the forming of a via 180 (S160), a connection structure is formed between the ground 140 and a second circuit 170 so as to connect the ground 140 with the second circuit 170 electrically. The via 180 may be formed within the insulation layer 150.

In the forming of the second circuit 170 (S170), the second circuit 170 configured for electrical connection with the ground 140 is formed on the insulation layer 150. Like the first circuit 120, the second circuit 170 may be formed by a modified semi additive process (MSAP) or a tenting process.

Referring to FIG. 12, in the removing of the core material C (S180), the core material C is separated from the printed circuit board. In the case where the core material C is constituted with the insulation material L, the first metal layer M1 and the second metal layer M2, the second metal layer M2 is already removed when the first circuit 120 is formed, and the insulation material L and the first metal layer M1 is removed in this step.

As described above, the first circuit 120 may be formed on one surface or both surfaces of the core material C. In the case where the first circuit 120 is formed on both surfaces of the core material C, the first circuit 120, the insulation film 130, the ground 140, the via 180 and the second circuit 170 are all formed on both surfaces of the core material C. Accordingly, by removing the core material C, two printed circuit boards may be formed.

In the forming of a first resist layer 110 and a second resist layer 190 (S190), the first resist layer 110 configured for protection of the first circuit 120 and the second resist layer 190 configured for protection of the second circuit 170 are formed. The first resist layer 110 and the second resist layer 190 may be formed with a solder resist.

The first resist layer 110 may be laminated beneath the first circuit 120, and the second resist layer 190 may be laminated on the second circuit 170. Moreover, the first resist layer 110 may have an opening 11 formed therein for exposing a portion of the first circuit 120, and the second resist layer 190 may also expose a portion of the second circuit 170.

The portion of the first circuit 120 that is exposed by the opening 111 of the first resist layer 110 and the portion of the second circuit 170 that is exposed by the second resist layer 190 may each function as a pad and may be surface-treated.

As described above, with the printed circuit board and the method of manufacturing the printed circuit board in accordance with an embodiment of the present invention, the thickness of the printed circuit board is reduced by the insulation film, making it possible to realize a thinner printed circuit board.

Although a certain embodiment of the present invention has been described above, it shall be appreciated that there can be a variety of permutations and modifications of the present invention by those who are ordinarily skilled in the art to which the present invention pertains without departing from the technical ideas and scope of the present invention, which shall be defined by the appended claims. It shall be also appreciated that a large number of other embodiments than the above-described embodiment are included in the claims of the present invention.

What is claimed is:

1. A printed circuit board comprising:
a first resist layer;
a first circuit formed on the first resist layer;
an insulation film formed on the first resist layer so as to cover an upper surface and a lateral surface of the first circuit;
a ground formed on the insulation film so as to be connected with the first circuit electrically; and
an insulation layer formed on the insulation film so as to cover the ground.

2. The printed circuit board of claim 1, further comprising a connecting portion penetrating the insulation film so as to be interposed between the first circuit and the ground.

3. The printed circuit board of claim 2, wherein the ground is made of a conductive material, and
wherein the connecting portion is formed by filling a hole formed in the insulation film with a conductive material that is the same as the conductive material of the ground.

4. The printed circuit board of claim 2, wherein one side of the connecting portion is in contact with the first circuit and the other side of the connecting portion is in contact with the ground.

5. The printed circuit board of claim 1, wherein a thickness of the insulation film is smaller than or equal to a thickness of the first circuit.

6. The printed circuit board of claim 1, wherein the insulation film is formed by use of deposition.

7. The printed circuit board of claim 1, further comprising a second circuit formed on the insulation layer for electrical connection with the ground.

8. The printed circuit board of claim 7, further comprising a via formed within the insulation layer so as to be interposed between the ground and the second circuit.

9. The printed circuit board of claim 7, further comprising a second resist layer formed on the insulation layer in such a way that a portion of the second circuit is exposed.

10. A method of manufacturing a printed circuit board, comprising:
providing a core material;
forming a first circuit on the core material;
forming an insulation film on the core material so as to cover an upper surface and a lateral surface of the first circuit;
forming a ground on the insulation film for electrical connection with the first circuit; and
forming an insulation layer on the insulation film for covering the ground.

11. The method of claim 10, further comprising, after the forming of the insulation film, forming a connecting portion penetrating the insulation film so as to be interposed between the first circuit and the ground.

12. The method of claim 11, wherein the ground and the connecting portion are made of a same conductive material.

13. The method of claim 12, wherein the forming of the connecting portion comprises:
forming a hole in the insulation film in such a way that a portion of the first circuit is exposed; and
filling the hole with the conductive material.

14. The method of claim 13, further comprising, between the forming of the hole in the insulation film and the filling of the hole with the conductive material, forming a seed layer on the insulation film so as to cover an inner wall of the hole,
wherein the filling of the hole with the conductive material comprises plating an inside of the hole with the conductive material.

15. The method of claim 14, further comprising, between the forming of the seed layer on the insulation film and the filling of the hole with the conductive material:
forming a photoresist on the seed layer; and
forming an opening area in the photoresist in such a way that the seed layer corresponding to the hole is exposed.

16. The method of claim 15, wherein a position of the opening area corresponds to a position of the ground, and
wherein the forming of the ground comprises plating an inside of the opening area with the conductive material.

17. The method of claim 16, wherein the inside of the hole and the inside of the opening area are plated simultaneously.

18. The method of claim 16, wherein the forming of the ground further comprises:
removing the photoresist; and
removing the seed layer that is exposed.

19. The method of claim 11, further comprising, after forming of the insulation layer, forming a second circuit on the insulation layer for electrical connection with the ground.

20. The method of claim 19, further comprising, between the forming of the insulation layer and the forming of the second circuit, forming a via in the insulation layer, the via being interposed between the ground and the second circuit.

21. The method of claim 19, further comprising, after the forming of the second circuit, removing the core material.

22. The method of claim 20, further comprising, after the removing of the core material:
forming a first resist layer beneath the first circuit; and
forming a second resist layer on the second circuit.
